(19) United States
(12) Patent Application Publication
(10) Pub. No.: US 2010/0047988 A1
(43) Pub. Date: Feb. 25, 2010

(54) METHODS OF FORMING A LAYER, METHODS OF FORMING A GATE STRUCTURE AND METHODS OF FORMING A CAPACITOR

(76) Inventors: Youn-Joung Cho, Gyeonggi-do (KR); Youn-Soo Kim, Gyeonggi-do (KR); Kyu-Ho Cho, Gyeonggi-do (KR); Jung-Ho Lee, Gyeonggi-do (KR); Jae-Hyoung Choi, Gyeonggi-do (KR); Seung-Min Ryu, Busan (KR)

Correspondence Address: MYERS BIGEL SIBLEY & SAJOVEC, PO BOX 37428, RALEIGH, NC, 27627, US

(21) Appl. No.: 12/542,813

(22) Filed: Aug. 18, 2009

(30) Foreign Application Priority Data
Aug. 19, 2008 (KR) 10-2008-0080833

(51) Int. Cl. H01L 21/02; C07F 7/00; H01L 21/28

(52) U.S. Cl. 438/381; 556/51; 438/585; 257/E21.19; 257/E21.011

(57) ABSTRACT

In a method of forming a layer, a precursor including a metal and a ligand coordinating to the metal is stabilized by contacting the precursor with an electron donating compound to provide a stabilized precursor into a substrate. A reactant is introduced into the substrate to bind to the metal in the stabilized precursor. The precursor stabilized by the electron donating compound has an improved thermal stability and thus the precursor is not dissociated at a high temperature atmosphere, and the layer having a uniform thickness is formed on the substrate.

### CROSS-REFERENCE TO RELATED PATENT APPLICATIONS

This application claims the benefit of Korean Patent Application No. 10-2008-0080833, filed on Aug. 19, 2008, in the Korean Intellectual Property Office, the disclosure of which is incorporated herein in its entirety by reference.

### BACKGROUND

Example embodiments relate to a precursor composition, methods of forming a layer, methods of manufacturing a gate structure and methods of manufacturing a capacitor. More particularly, example embodiments relate to a precursor composition having an improved thermal stability, methods of forming a layer having good step coverage and methods of manufacturing a gate structure and a capacitor using the same.

Generally, semiconductor devices having a higher integration degree and rapid response speed are desirable. The technology of manufacturing the semiconductor devices has improved the integration degree, reliability and/or response speed of semiconductor devices. As the integration degree of the semiconductor devices increases, a design rule of the semiconductor devices may decrease.

The semiconductor devices generally may include conductive structures (e.g., wirings, plugs, conductive regions or electrodes) and insulation structures (e.g., dielectric layers, or insulating interlayers) that may electrically isolate the conductive structures. Forming such structures may include a film deposition process. Examples of the film deposition process may include a physical vapor deposition (PVD) process, a chemical vapor deposition (CVD) process, or an atomic layer deposition (ALD) process.

The PVD process has an undesirable property in that it fills a hole, a gap or a trench, and thus generates a void in the hole, the gap or the trench. As the integration degree of the semiconductor device increases, a width of the hole may become narrow and an aspect ratio of the hole may be increased. When the width of the hole is smaller and the aspect ratio of the hole is larger, a depositing material may be readily accumulated on an entrance of the hole to prevent the entrance of the hole prior to completely filling the inside of the hole and to generate a void in the hole. The void may increase an electrical resistance of a conductive structure to deteriorate performance of the semiconductor device and to cause a defect of the semiconductor device. However, the CVD process or the ALD process may have an improved property that fills the hole as compared with the PVD process, and thus may be employed in filling the hole, the gap or the trench in a semiconductor manufacturing process.

In the CVD process or the ALD process, a precursor is introduced into a chamber using a bubbling system or an injection system. For example, in the bubbling system, a precursor of a liquid state or a solid state is vaporized by bubbling the precursor with a carrier gas, and the vaporized precursor is introduced into the chamber with the carrier gas. That is, the precursor of the liquid state or the solid state is vaporized before introducing into the chamber to transform into the vapor state. As a result, the precursor is heated and a chamber maintains a high temperature during introduction of the precursor into the chamber. Thus, a high thermal stability may be required in the precursor used for forming the layer. When the precursor is unstable to heat and to be easily dissociated, it is difficult to control a process condition and to form a layer having a uniform thickness. Thus, electrical characteristics of the semiconductor devices may be deteriorated.

### SUMMARY

Example embodiments provide a precursor composition having an improved thermal stability.

Example embodiments provide a method of forming a layer having good step coverage by utilizing the precursor having an improved thermal stability.

Example embodiments provide a method of manufacturing a gate structure using the precursor having an improved thermal stability.

Example embodiments provide a method of manufacturing a capacitor using the precursor having an improved thermal stability.

According to some example embodiments, there is provided a method of forming a layer. In the method, a precursor including a metal and a ligand coordinating to the metal is stabilized by contacting the precursor with an electron donating compound to provide a stabilized precursor into a substrate. A reactant is introduced into the substrate to bind to the metal in the stabilized precursor.

In example embodiments, the electron donating compound may include water, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a 13-diketone compound having a carbon atom of about 5 to about 20, a β-ketoimine compound having a carbon atom of about 5 to about 20, a β-diimine compound having a carbon atom of about 5 to about 20, ammonia or a amine compound having a carbon compound of about 1 to about 10. These may be used alone or in a mixture thereof.

In example embodiments, the metal in the precursor may include lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), cesium (Cs), barium (Ba), lanthanum (La), lanthanide (Ln), hafnium (Hf), tantalum (Ta), tungsten (W), rhenium (Re), osmium (Os), iridium (Ir), platinum (Pt), gold (Ag), thallium (Tl), mercury (Hg), lead (Pb), bismuth (Bi), polonium (Po), francium (Fr), radium (Ra), actinium (Ac) and actinide (An). In example embodiments, the metal in the precursor may include zirconium or hafnium and the electron donating compound may include a primary amine, a secondary amine or a tertiary amine. The primary amine, the secondary amine and the tertiary amine may have a carbon atom of about 1 to about 10.

In example embodiments, the secondary amine may include dimethyl amine, diethyl amine or ethyl methyl amine and the tertiary amine may include ethyl dimethyl amine, diethyl methyl amine or triethyl amine.

In example embodiments, the electron donating compound is contacted with the precursor including zirconium or hafnium to form the stabilized precursor represented by formula 1

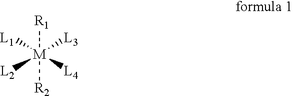

In the formula 1, M may represent zirconium or hafnium, L1 to L4 may independently represent fluoro (F), chloro (Cl), bromo (Br), iodo (I), an alkoxy group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a β-ketoiminato group having a carbon atom of about 5 to about 20, a β-diiminato group having a carbon atom of about 5 to about 20, a hydroxyl group (OH), ammine (NH₃), an amine group having a carbon atom of about 1 to 10, amido (NH2) or an amido group in which an alkyl group having a carbon atom of about 1 to about 10 is substituted for a hydrogen atom and R₁ and R₂ may independently represent hydrogen fluoride (HF), hydrogen chloride (HCl), hydrogen bromide (HBr), hydrogen iodide (HI), water, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound of having a carbon atom of about 5 to about 20, a β-ketoimine compound having a carbon atom of about 5 to about 20, a β-diimine compound having a carbon atom of about 5 to about 20, ammonia or an amine compound having a carbon atom of about 1 to about 10.

In example embodiments, the precursor may include tetrakis-ethylmethylamido-zirconium (Zr(NCH₃C₂H₅)₄), tetrakis-ethylmethylamido-hafnium (Hf(NCH₃C₂H₅)₄), tetrakis-diethylamido-zirconium (Zr(N(C₂H₅)₂)₄), tetrakis-diethylamidohamido-hafnium (Hf(N(C₂H₅)₂)₄), tetrakis-dimethylamido-zirconium (Zr(N(CH₃)₂)₄), tetrakis-dimethylamido-hafnium (Hf(N(CH₃)₂)₄), tetrakis-ethyldimethylamine-zirconium (Zr(N(CH₃)₂C₂H₅)₄), tetrakis-ethyldimethylamine-hafnium (Hf(N(CH₃)₂C₂H₅)₄, tetrakis-diethylmethylamine-zirconium (Zr(N(C₂H₅)₂CH₃)₄), tetrakis-diethylmethylamine-hafnium (Hf(N(C₂H₅)₂CH₃)₄), tetrakis-triethylamine-zirconium (Zr(N(C₂H₅)₃)₄) or tetrakis-triethylamine-hafnium (Hf(N(C₂H₅)₃)₄). These may be used alone or in a mixture thereof.

In example embodiments, the precursor may be mixed with the electron donating compound to prepare a precursor composition. The precursor composition may be vaporized to provide the stabilized precursor into the substrate.

In example embodiments, the precursor may include the precursor and the electron donating compound with a mole ratio of about 1:0.01 to about 1:12.

In example embodiments, the precursor and the electron donating compound may be introduced into the substrate, respectively. The precursor may be contacted with the electron donating compound on the substrate to provide the stabilized precursor into the substrate.

In example embodiments, the precursor and the electron donating compound may be simultaneously introduced into the substrate during the same time interval.

In example embodiments, the electron donating compound may be further introduced into the substrate after the precursor and the electron donating compound are introduced into the substrate during the same time interval.

In example embodiments, the electron donating compound may be introduced after the precursor is introduced into the substrate.

In example embodiments, the precursor may be introduced after the electron donating compound is introduced into the substrate.

According to some example embodiments, there is provided a method of forming a gate structure. In the method, a precursor including a metal and a ligand coordinating to the metal is stabilized by contacting the precursor with an electron donating compound to provide a stabilized precursor into a substrate. A reactant binding to the metal in the stabilized precursor is introduced into the substrate to form a gate insulation layer. A gate conductive layer is formed on the gate insulation layer. A gate conductive layer is formed on the gate insulation layer. The gate insulation layer and the gate conductive layer are etched.

According to some example embodiments, there is provided a method of forming a capacitor. In the method, a lower electrode is formed on a substrate. A precursor including a metal and a ligand coordinating to the metal is stabilized by contacting the precursor with an electron donating compound to provide a stabilized precursor into a substrate. A reactant binding to the metal of the precursor into the substrate is introduced to form a dielectric layer. An upper electrode is formed on the dielectric layer.

According to some example embodiments, a precursor composition used for a vapor deposition process is provided. The precursor composition includes an electron donating compound and a precursor including a metal and a ligand coordinating to the metal.

In example embodiments, the precursor composition may include the precursor and the electron donating compound with a mole ratio of about 1:0.01 to about 1:12.

In example embodiments, the precursor composition may include a first precursor including a first metal and a second precursor including a second metal substantially different from the second metal.

In example embodiments, the precursor composition may include the first precursor including the first metal, the second precursor including the second metal and a third precursor including a third metal substantially different from the first metal and the second metal.

According to some example embodiments, the precursor stabilized by the electron donating compound has an improved thermal stability. That is, the precursor stabilized by the electron donating compound is not dissociated at a high temperature atmosphere. Accordingly, when the layer is formed using the precursor stabilized by the electron donating compound, the precursor may be uniformly diffused into the lower portion of a hole, a trench, a gap or a recess without dissociation of the precursor. As a result, the layer having good step coverage may be efficiently formed on an object and thus semiconductor devices having an improved stability and reliability may be manufactured.

### BRIEF DESCRIPTION OF THE DRAWINGS

FIGS. 1 and 2 are flow charts illustrating a method of forming a layer in accordance with example embodiments.

FIGS. 3, 4 and 6 to 8 are cross sectional views illustrating a method of forming a layer in accordance with example embodiments.

FIGS. 5A to 5D are timing sheets illustrating a method of forming a layer in accordance with example embodiments.

FIGS. 9 to 11 are cross sectional views illustrating a method of manufacturing a gate structure in accordance with example embodiments.

FIGS. 12 to 15 are cross sectional views illustrating a method of manufacturing a capacitor in accordance with example embodiments.

FIG. 18 is a graph illustrating a ratio of solid residues weight with respect to a vaporized weight of the precursor composition and a comparative composition.

FIG. 17 is a graph illustrating a thickness of a layer formed by an ALD process.

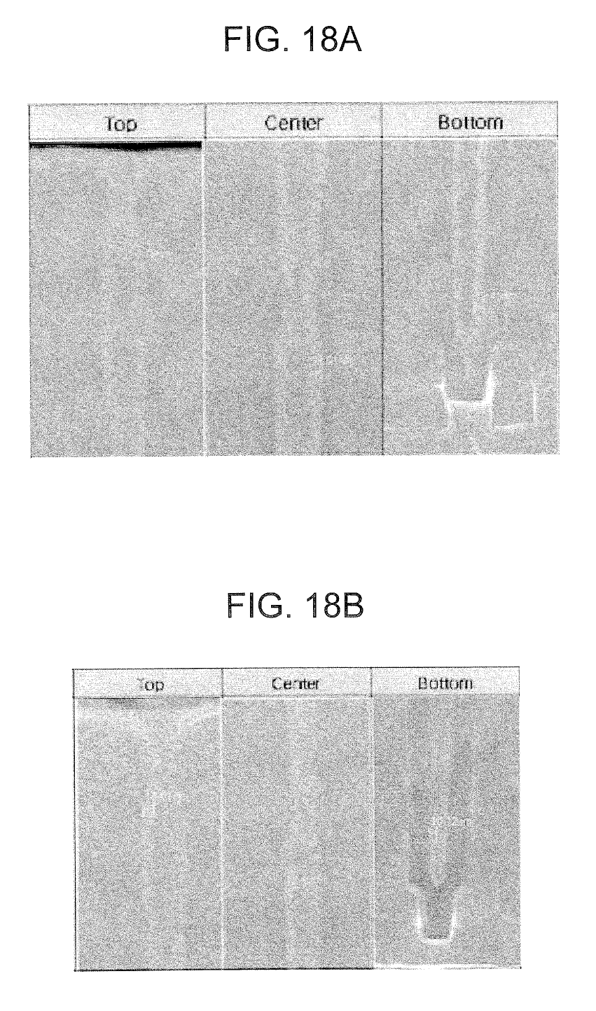

FIGS. 18A and 18B are scanning electron microscope (SEM) pictures illustrating a capacitor.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

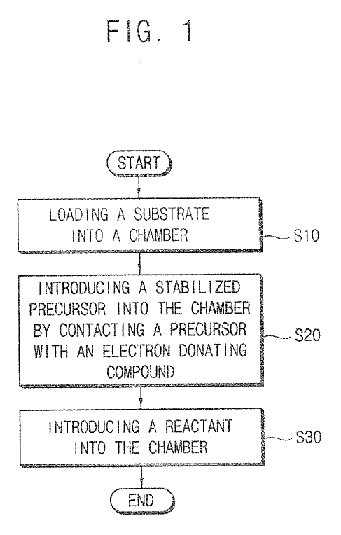

FIG. 1 is a flow chart illustrating a method of forming a layer in accordance with example embodiments. Referring to FIG. 1, a substrate on which a layer will be formed is loaded in a chamber (S 10). The substrate may include a semiconductor substrate such as silicon substrate, a germanium substrate, a silicon-germanium substrate, a silicon-on-insulator (SOI) substrate, a germanium-on-insulator (GOI) substrate, etc. Alternatively, the substrate may include a single crystalline metal oxide substrate. For example, the substrate may include a single crystalline aluminum oxide (Al₂O₃) substrate, a single crystalline strontium titanium oxide (SrTiO₃) substrate or a single crystalline magnesium oxide (MgO) substrate. The substrate may be placed on a susceptor in the chamber. A temperature and/or a pressure of the chamber may be properly adjusted to perform a deposition process of the layer.

A precursor is contacted with an electron donating compound to provide a stabilized precursor on the substrate (S 20). In example embodiments, the precursor includes a metal and a ligand coordinating to the metal. The metal in the precursor may be a material which will be included in the layer. The electron donating compound may provide an electron to the precursor to improve a thermal stability of the precursor.

The precursor may maintain a vapor state in the chamber before the precursor is chemisorbed on a surface of the substrate. Accordingly, when the precursor may be unstable to heat, the precursor may be decomposed before the precursor is chemisorbed on the surface of the substrate. When the precursor may be decomposed prior to being chemisorbed on the surface of the substrate, precipitates generated by a decomposition of the precursor may prevent diffusion of the precursor introduced into the chamber. For example, when the substrate has a stepped portion, precipitates caused by the decomposition of the precursor may be deposited on an upper portion of the stepped portion and thus the precursor may not be uniformly diffused into a lower portion of the stepped portion. Hence, the layer having a uniform thickness may not be formed along the profile of the stepped portion of the substrate. That is, a thick layer may be formed on an upper portion of the stepped portion to deteriorate the step coverage of the layer on the substrate. However, when the precursor is contacted with the electron donating compound, the precursor may not be decomposed at a high temperature atmosphere to maintain the vapor state in the chamber for a long time. Therefore, the stabilized precursor, which is formed by contacting the precursor with the electron donating compound, may be efficiently diffused into the lower portion of the stepped portion to form the layer having a good step coverage on the stepped portion of the substrate.

In example embodiments, the precursor may include the metal and the ligand coordinating to the metal. The metal may be adjusted according to properties of the layer formed on the substrate. The metal in the precursor may include lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), cesium (Cs), barium (Ba), lanthanum (La), lanthanide (Ln), hafnium (Hf), tantalum (Ta), tungsten (W), rhenium (Re), osmium (Os), iridium (Ir), platinum (Pt), gold (Ag), thallium (Tl), mercury (Hg), lead (Pb), bismuth (Bi), polonium (Po), francium (Fr), radium (Ra), actinium (Ac) or actinide (An). For example, the metal may include zirconium or hafnium.

The ligand coordinating to the metal may be varied according to the metal to adjust a boiling point of the precursor. In example embodiments, the ligand may include a halogen such as fluoro (F), chloro (Cl), bromo (Br) or iodo (I), a hydroxyl group (OH), ammine (NH₃), an amine group having a carbon atom of about 1 to 10, amido (NH₂) or an amido group in which an alkyl group having a carbon atom of about 1 to about 10 is substituted for a hydrogen atom, an alkoxy group having a carbon atom of about 1 to about 10, an alkyl group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a β-ketoiminato group having a carbon atom of about 5 to about 20 or a β-diiminato group having a carbon atom of about 5 to about 20. These may be used alone or in a mixture thereof. For example, the ligand may be dimethylamido (N(CH₃)₂), ethyl methyl amido (NCH₃C₂H₅), diethylamido (N(C₂H₅)₂), ethyl dimethyl amine (N(CH₃)₂C₂H₅), diethyl methyl amine (N(C₂H₅)₂CH₃) or triethylamine (N(C₂H₅)₂)₃).

In example embodiments, the precursor having the metal and the ligand may include tetrakis-ethylmethylamido-zirconium (Zr(NCH₃C₂H₅)₄), tetrakis-ethylmethylamido-hafnium (Hf(NCH₃C₂H₅)₄), tetrakis-diethylamido-zirconium (Zr(N(C₂H₅)₂)₄), tetrakis-diethylamido-hafnium (Hf(N(C₂H₅)₂)₄), tetrakis-dimethylamido-zirconium (Zr(N(CH₃)₂)₄), tetrakis-dimethylamido-hafnium (Hf(N(CH₃)₂)₄), tetrakis-ethyldimethylamine-zirconium (Zr(N(CH₃)₂C₂H₅)₄), tetrakis-ethyldimethylamine-hafnium (Hf(N(CH₃)₂C₂H₅)₄), tetrakis-diethylmethylamine-zirconium (Zr(N(C₂H₅)₂CH₃)₄), tetrakis-diethylmethylamine-hafnium (Hf(N(C₂H₅)₂CH₃)₄), tetrakis-triethylamine-zirconium (Zr(N(C₂H₅)₃)₄) or tetrakis-triethylamine-hafnium (Hf(N(C₂H₅)₃)₄). These may be used alone or in a mixture thereof.

The electron donating compound may have a lone pair electron or a high electron density to donor an electron to a portion having a positive charge or electron deficiency portion of the precursor. Various materials capable of providing an electron may be used as the electron donating compound. When the electron donating compound donates an electron to the metal of the precursor, an intermolecular interaction between the metal of the precursor and the electron donating compound may be generated to stabilize the precursor. The intermolecular interaction between the metal of the precursor and the electron donating compound may be substantially weaker than a bonding force between the metal and the ligand in the precursor. Therefore, when the precursor is chemisorbed onto the surface of the substrate or is reacted with other reactants, the intermolecular interaction between the metal of the precursor and the electron donating compound may be easily removed to detach the electron donating compound from the precursor.

The electron donating compound may include a compound having a lone pair electron or an electron-rich compound such as allyl compound, an aryl compound, a diene compound or β-diketone compound. In example embodiments, the electron donating compound may be water, hydrogen halide, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound having a carbon atom of about 5 to about 20, a β-ketoimine compound having a carbon atom of about 5 to about 20, a β-diimine compound having a carbon atom of about 5 to about 20, ammonia or an amine compound having a carbon compound of about 1 to about 10. These may be used alone or in a mixture thereof. Hydrogen halide may include hydrogen fluoride, hydrogen chloride, hydrogen bromide or hydrogen iodide. The diene compound may include cyclopentadiene or a cyclopentadiene in which an alkyl compound having a carbon atom of about 1 to about 10 is substituted for a hydrogen atom. The alcohol compound may include ethanol, methanol or butanol. The amine compound having a carbon atom of about 1 to about 10 may include a primary amine, a secondary amine or tertiary amine. For example, the electron donating compound may include diethyl amine, dimethyl amine, ethyl methyl amine, ethyl dimethyl amine, diethyl methyl amine or triethyl amine.

In example embodiments, when the precursor including zirconium or hafnium is contacted with the electron donating compound, zirconium or hafnium in the precursor may interact with the electron donating compound as illustrated in formula (1) to improve a thermal stability of the precursor.

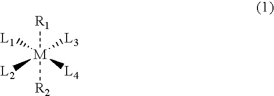

In the formula (1), M may represent a central metal such as zirconium or hafnium. L₁ to L₄ may be a ligand coordinating to the central metal and independently represent fluoro (F), chloro (Cl), bromo (Br), iodo (I), an alkoxy group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a βketoiminato group having a carbon atom of about 5 to about 20, a β-diiminato group having a carbon atom of about 5 to about 20, a hydroxyl group (OH), ammine (NH₃), an amine group having a carbon atom of about 1 to 10, an amido group (NH₂) or an amido group in which an alkyl group having a carbon atom of about 1 to about 10 is substituted for a hydrogen atom. R₁ and R₂ may be an electron donating compound which interact with the central metal to stabilize the precursor and independently represent (HF), hydrogen chloride (HCl), hydrogen bromide (HBr), hydrogen iodide (HI), an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound having a carbon atom of about 5 to about 20, a β-ketoimine compound having a carbon atom of about 5 to about 20, a β-diimine compound having a carbon atom of about 5 to about 20, ammonia or an amine compound having a carbon atom of about 1 to about 10. For example, L₁ to L₄ may be dimethyl amido, diethyl amido. ethyl methyl amido, ethyl dimethyl amine, diethyl methyl amine or triethyl amine and R₁ and R₂ may be dimethyl amine, diethyl amine, ethyl methyl amine, ethyl dimethyl amine, diethyl methyl amine or triethylamine.

As illustrated in formula (1), zirconium or hafnium may have a coordination number of four. Therefore, zirconium or hafnium may coordinate to four ligands to form a precursor. When the precursor is contacted with the electron donating compound, the electron donating compound may donate an electron to zirconium or hafnium to stabilize the precursor. Hence, when the precursor is contacted with the electron donating compound, the stabilized precursor may have an octahedral structure similar to that of a complex compound including a central metal and a six ligand coordinating to the central metal. However, the intermolecular interaction between zirconium or hafnium and the electron donating compound may be substantially weaker than a bonding force between zirconium or hafnium and the ligand.

In one example embodiment, the precursor may be contacted with the electron donating compound before the precursor is introduced into the chamber. The precursor and the electron donating compound may be a solid state or a liquid state at a room temperature. When the precursor and the electron donating compound is in a liquid state at a room temperature, a precursor composition may be formed by mixing the precursor and the electron donating compound to stabilize the precursor. When the precursor is in a solid state at a room temperature, the precursor may be heated by a melting point to be transformed into the liquid state. A precursor composition may be formed by mixing the precursor in the liquid state and the electron donating compound to stabilize the precursor. In other example embodiment, the precursor may be contacted with the electron donating compound in the chamber. For example, after the precursor and the electron donating compound are vaporized to be introduced into the chamber, respectively, the vaporized precursor may be contacted with the vaporized electron donating compound in the chamber to stabilize the precursor.

The stabilized precursor is provided on the substrate. When the precursor and the electron donating compound are mixed to form the precursor composition, the stabilized precursor may be introduced into the chamber by vaporizing the precursor composition to provide the stabilized precursor onto the substrate. When the vaporized precursor and the vaporized electron donating compound are introduced into the chamber, respectively, the stabilized precursor may be provided onto the substrate by contacting the vaporized precursor with the vaporizing electron donating compound in the chamber.

A reactant is introduced into the chamber to form a layer on the substrate (S30). The reactant may bind to the metal to form a metal compound. When the layer is formed using the precursor stabilized by the electron donating compound, the layer may have a good step coverage.

A reactant may be adjusted by properties of the layer. When the layer is a metal oxide layer, the reactant may include an oxidant such as water or water vapor (H₂O), ozone (O₃), oxygen (O₂), an oxygen plasma or an ozone plasma, etc. When the layer is a metal nitride layer, the reactant may include ammonia (NH₃), nitrogen dioxide (NO₂) or nitrous oxide (N₂O), etc.

When the reactant is introduced into the chamber, the reactant may be substituted for the ligand to form the metal oxide layer or the metal nitride layer on the substrate. In one example embodiment, the layer may be formed by a chemical vapor deposition (CVD) process. That is, after the ligand in the precursor is replaced with the reactant to form the metal compound, the metal compound may be chemisorbed onto the substrate. In other example embodiment, the layer may be formed by an atomic layer deposition (ALD) process. That is, after the stabilized precursor is chemisorbed on the substrate, the ligand in the chemisorbed precursor may be replaced with the reactant to form the layer on the substrate.

According to example embodiments, the layer may be formed using the precursor stabilized by the electron donating compound. The electron donating compound may improve the thermal stability of the precursor and thus the precursor may not be decomposed at a high temperature for a long time without change to a structure or properties of the precursor. Hence, when the layer is formed using the stabilized precursor, precipitates caused by decomposition of the precursor may not be deposited to prevent the precipitates from filling a hole, a gap, a trench or a recess. Further, the precursor may be diffused into the lower portion of the stepped portion to form the layer having a uniform thickness.

Hereinafter, example embodiments will be explained in detail with reference to the accompanying drawings.

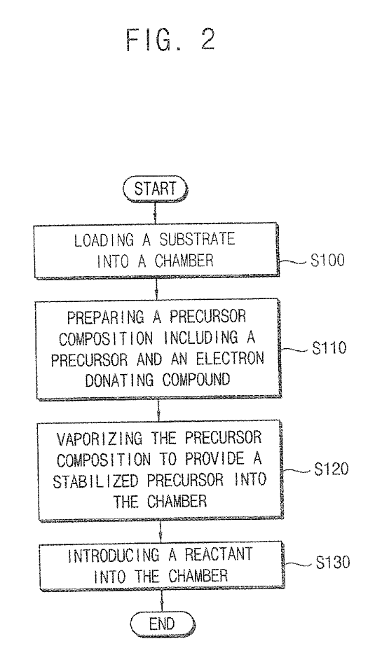

FIG. 2 is a flow chart illustrating a method of forming a layer in accordance with example embodiments.

Referring to FIG. 2, a substrate on which a layer will be formed is loaded in a chamber (S100). The substrate may include a semiconductor substrate such as silicon substrate, a germanium substrate, a silicon-germanium substrate, a silicon-on-insulator (SOI) substrate, a germanium-on-insulator (GOI) substrate, etc. Alternatively, the substrate may include a single crystalline metal oxide substrate. For example, the substrate may include a single crystalline aluminum oxide (Al₂O₃) substrate, a single crystalline strontium titanium oxide (SrTiO₃) substrate or a single crystalline magnesium oxide (MgO) substrate.

Referring to FIG. 2, a precursor and an electron donating compound are mixed to prepare a precursor solution (S110). The precursor includes a metal and a ligand coordinating to the metal. The electron donating compound may provide an electron to the precursor to improve a thermal stability of the precursor.

In example embodiments, the precursor may include the metal and the ligand coordinating to the metal. The metal may be adjusted according to properties of the layer formed on the substrate. The metal in the precursor may include lithium, beryllium, boron, sodium, magnesium, aluminum, potassium, calcium, scandium, titanium, vanadium, chromium, manganese, iron, cobalt, nickel, copper, zinc, gallium, germanium, rubidium, strontium, yttrium, zirconium, niobium, molybdenum, technetium, ruthenium, rhodium, palladium, silver, cadmium, indium, tin, antimony, tellurium, cesium, barium, lanthanum, lanthanide, hafnium, tantalum, tungsten, rhenium, osmium, iridium, platinum, gold, thallium, mercury, lead, bismuth, polonium, francium, radium, actinium or actinide. For example, the metal may include zirconium or hafnium.

The ligand coordinating to the metal may be varied according to the metal to adjust a boiling point of the precursor. In example embodiments, the ligand may include a halogen such as fluoro, chloro, bromo or iodo, a hydroxyl group, ammine, an amine group having a carbon atom of about 1 to 10, amido or an amido group in which an alkyl group having a carbon atom of about 1 to about 10 is substituted for a hydrogen atom, an alkoxy group having a carbon atom of about 1 to about 10, an alkyl group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a β-ketoiminato group having a carbon atom of about 5 to about 20 or a β-diiminato group having a carbon atom of about 5 to about 20. These may be used alone or in a mixture thereof. For example, the ligand may be dimethylamido (N(CH₃)₂), ethyl methyl amido (NCH₃C₂H₅), diethylamido (N(C₂H₅)₂), ethyl dimethyl amine (N(CH₃)₂C₂H₅), diethyl methyl amine (N(C₂H₅)₂CH₃) or triethylamine (N(C₂H₅)₃).

In example embodiments, the precursor having the metal and the ligand may include tetrakis-ethylmethylamido-zirconium (Zr(NCH₃C₂H₅)₄), tetrakis-ethylmethylamido-hafnium (Hf(NCH₃C₂H₅)₄), tetrakis-diethylamido-zirconium (Zr(N(C₂H₅)₂)₄), tetrakis-diethylamido-hafnium (Hf(N(C₂H₅)₂)₄), tetrakis-dimethylamido-zirconium (Zr(N(CH₃)₂)4), tetrakis-dimethylamido-hafnium (Hf(N(CH₃)₂)₄), tetrakis-ethyldimethylamine-zirconium (Zr(N(CH₃)₂C₂H₅)₄), tetrakis-ethyldimethylamine-hafnium (Hf(N(CH₃)₂C₂H₅)4), tetrakis-diethylmethylamine-zirconium (Zr(N(C₂H₅)₂CH₃)₄), tetrakis-diethylmethylamine-hafnium (Hf(N(C₂H₅)₂CH₃)₄), tetrakis-triethylamine-zirconium (Zr(N(C₂H₅)₃)₄) or tetrakis-triethylamine-hafnium (Hf(N(C₂H₅)₃)₄). These may be used alone or in a mixture thereof.

In one example embodiment, the precursor composition may include one type of the precursor. In another example embodiment, the precursor composition may include a first precursor having a first metal and a second compound having a second metal substantially different from the first metal. For example, the precursor composition may include the first precursor having zirconium as the first metal and the second precursor having hafnium as the second metal. In still another example embodiment, the precursor composition may include the first precursor having a first metal, a second compound having a second metal substantially different from the first metal and a third precursor having a third metal substantially different from the first metal and the second metal. For example, the precursor may include the first precursor having zirconium as the first metal, the second precursor having hafnium as the second metal and the third precursor having silicon as the third metal.

In example embodiments, the electron donating compound may be water, hydrogen halide, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound having a carbon atom of about 5 to about 20, a β-ketoimine compound having a carbon atom of about 5 to about 20, a β-diimine compound having a carbon atom of about 5 to about 20, ammonia or a amine compound having a carbon atom of about 1 to about 10. Theses may be used alone or in a mixture thereof. Hydrogen halide may include hydrogen fluoride, hydrogen chloride, hydrogen bromide or hydrogen iodide.

The precursor and the electron donating compound may be in a liquid state or in a solid state. When the precursor is in the solid state, the precursor may be dissolved into the electron donating compound in the liquid state to prepare a solution. The solution may be heated at a temperature between a melting point of the precursor and a boiling point of the electron donating compound to prepare a precursor composition. When both the precursor and the electron donating compound are in the liquid state, the precursor and the electron donating compound are mixed according to the predetermined ratio to prepare a precursor composition. In example embodiments, when the metal included in the precursor is zirconium or hafnium, the ligand may include diethylamido, dimethylamido, ethyl methyl amido, ethyl dimethyl amine, diethyl methyl amine or triethylamine and the electron donating compound may include a primary amine, a secondary amine or a tertiary amine having a carbon atom of about 1 to about 10, the precursor solution may be easily prepared because the precursor and the electron donating compound are in the liquid state at a room temperature.

In example embodiments, the precursor and the electron donating compound in the precursor composition may have a mole ratio of about 1:0.01 to about 1:12. When the precursor and the electron donating compound in the precursor composition may have a mole ratio less than about 1:0.01, the precursor may not be efficiently stabilized by the electron donating compound. The precursor and the electron donating compound in the precursor composition may have a mole ratio of about 1:0.5 to about 1:5.

Referring to FIG. 2, the precursor composition is vaporized to provide a stabilized precursor on the substrate in the chamber (S120).

In example embodiments, the stabilized precursor may be provided on the substrate in the chamber using a bubbling system, an injection system or a liquid delivery system (LDS). For example, when the stabilized precursor may be provided on the substrate using the liquid delivery system, the precursor composition including the precursor and the electron donating compound are carried into a vaporizer in a canister to be vaporized. Then, the stabilized precursor in a vapor state may be introduced into the chamber with a carrier gas. A thermal stability of the stabilized precursor may be improved by an electron of the electron donating compound. Accordingly, when a temperature of the precursor solution or a temperature of the vaporizer is rapidly increased, the stabilized precursor may not be dissociated for a long time. Additionally, the stabilized precursor may not be dissociated in the chamber having a high temperature atmosphere before a reactant is not introduced into the chamber. However, when the precursor is not mixed with the electron donating compound, the precursor may be easily dissociated because the precursor does not have an improved thermal stability. Thus, the precursor may be dissociated in the canister or the vaporizer during vaporizing the precursor. Additionally, a dissociated precursor may be attached on a gas line connected with the chamber. In accordance with example embodiments, the precursor may be contacted with the electron donating compound before the precursor is introduced into the chamber to have an improved thermal stability. Thus, the vaporized precursor may be efficiently carried into the chamber in which the substrate is loaded.

The carrier gas which is introduced with the vaporized precursor may be an inactive gas. For example, the carrier gas may include an argon gas, a helium gas, a nitrogen gas or a neon gas. These may be used alone or in a mixture thereof.

A flow rate of the carrier gas may be adjusted according to a deposition rate of the layer, a vapor pressure of the precursor or a temperature of the chamber. For example, the flow rate of the carrier gas may be about 200 sccm (standard cubic centimeters per minute) to about 1,300 sccm.

An interior of the chamber may have a substantially higher temperature than that of the canister or the gas line through which the vaporized precursor is introduced in the chamber. When the vaporized precursor is introduced into the interior of the chamber, the precursor may be dissociated in the chamber to generate precipitates. However, the precursor stabilized by the electron donating compound may have an improved thermal stability, and thus the stabilized precursor may not be dissociated in the chamber having a high temperature atmosphere.

In one example embodiment, when the layer is formed by an atomic layer deposition (ALD) process, after the stabilized precursor is provided into the chamber, a first purge gas may be introduced into the chamber. In the ALD process, the precursor may be chemisorbed on the substrate by introducing the stabilized precursor into the chamber. Then the first purge gas may be introduced into the chamber to remove a non-chemisorbed precursor from the chamber.

Referring to FIG. 2, a reactant binding to the metal in the precursor is introduced into the chamber (S130). The reactant may be adjusted according to properties of the layer. When the layer is an oxide layer, the reactant may include ozone (O₃), oxygen (O₂), water (H₂O), an oxygen plasma, an ozone plasma, etc. These may be used alone or in a mixture thereof. When the layer is a nitride layer, the reactant may include ammonia (NH₃), nitrogen dioxide (NO₂) or nitrous oxide (N₂O), etc.

When the reactant is introduced into the chamber, the reactant may bind to the metal in the precursor by substituting for the ligand in the precursor to form the layer on the substrate.

In example embodiments, after the reactant is introduced into the chamber, a second purge gas is provided on the substrate in the chamber. The introduction of the second purge gas may remove a remaining reactant which does not bind to the metal in the precursor or the precursor which does not chemisorbed on the substrate.

According to example embodiments, before the precursor is introduced into the chamber, the precursor composition may be prepared by mixing the precursor and the electron donating compound to form the stabilized precursor. The precursor stabilized by the electron donating compound may have improved thermal stability. Furthermore, the stabilized precursor may not be dissociated at a high temperature atmosphere when the stabilized precursor is the liquid state or the vapor state. As a result, the stabilized precursor may not be dissociated during vaporizing the precursor and thus the precipitates caused by a dissociation of the precursor may be prevented from depositing on the canister or the gas line connected to the chamber. Additionally, the stabilized precursor of the vapor state may not be dissociated in the chamber having a high temperature atmosphere because the stabilized precursor of the vapor state may have improved thermal stability. Thus, the precipitates caused by a dissociation of the precursor may be prevented from depositing on the substrate or the chamber. Further, the stabilized precursor may maintain the vapor state without dissociation to be uniformly diffused into a lower portion of a hole, a trench, a gap or a recess.

Hereinafter, a method of forming a layer in accordance with example embodiments will be explained in detail with reference to the accompanying drawings.

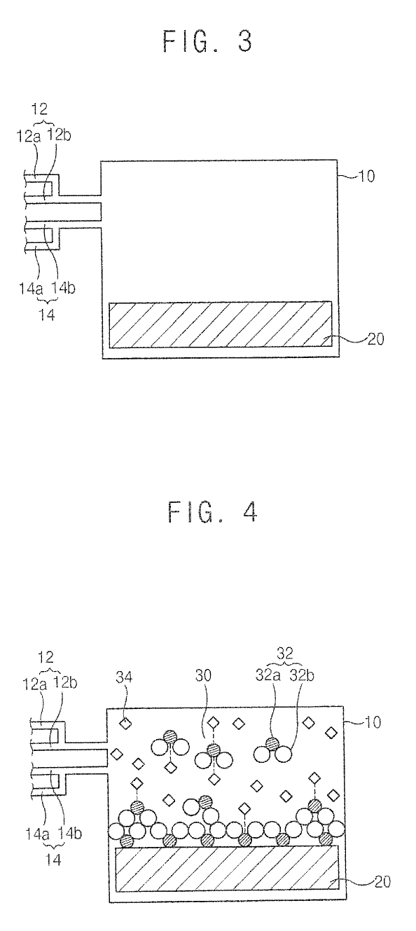

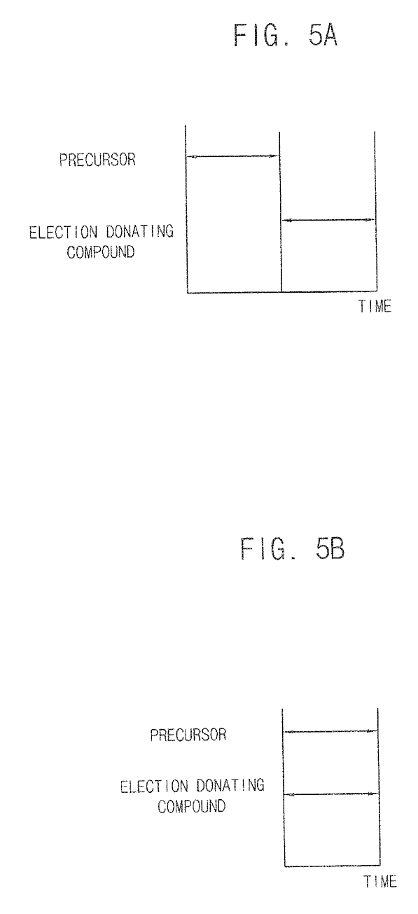

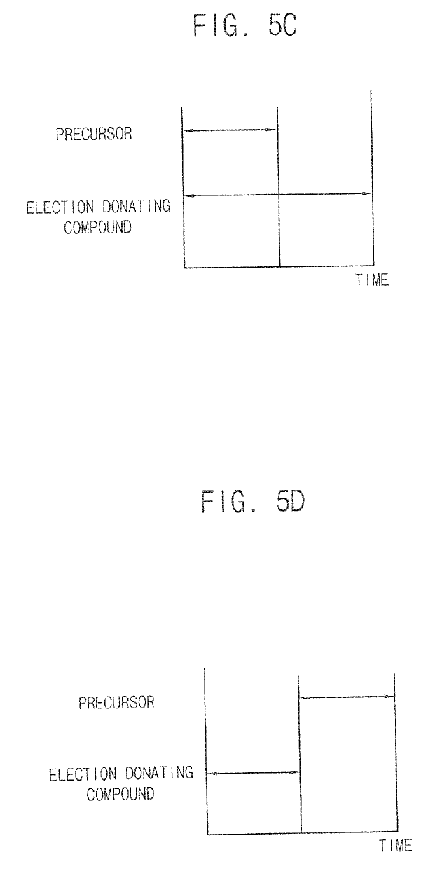

FIGS. 3 to 5, 7 and 8 illustrate a method of forming a layer in accordance with example embodiments, FIGS. 5A to 5D are timing sheets illustrating an introduction order and an introduction time interval of a precursor and an electron donating compound in accordance with example embodiments.

Referring to FIG. 3, a substrate 20 is loaded into a chamber 10. The chamber 10 may include gas lines 12 and 14 for introducing a gas into the chamber 10. In example embodiments, the gas lines 12 and 14 may include a first gas line 12 and a second gas line 14. The first gas line 12 may includes a first diverged line 12a and a second diverged line 12b. A precursor 32 and an electron donating compound 34 (see FIG. 4) may be introduced into the chamber 10 through the first diverged line 12a and a first purge gas may be introduced into the chamber 10 through the second diverged line 12b. The second gas line 14 may include a third diverged line 14a and a fourth diverged line 14b. A reactant 50 (see FIG. 4) binding to a metal 32a (see FIG. 4) in the precursor 32 may be introduced into the chamber 10 through the third diverged line 14a and a second purge gas may be introduced into the chamber 10 through the fourth diverged line 14b.

Referring to FIG. 4, the precursor 32 and the electron donating compound 34 are introduced into the chamber 10 to provide a stabilized precursor 30 on the substrate 20. When the precursor 32 of a vapor state is contacted with the electron donating compound 34 of a vapor state on the substrate 20, the electron donating compound 34 may donate an electron to the metal 32a in the precursor 32 to generate an intermolecular interaction between the electron donating compound 34 and the precursor 32. The stabilized precursor 30 may have an improved thermal stability and thus the stabilized precursor may not be dissociated at a high temperature atmosphere.

In example embodiments, the precursor 32 includes the metal 32a and a ligand 32b coordinating to the metal 32a. The metal 32a may be adjusted according to properties of the layer formed on the substrate 20. The metal 32a in the precursor 32 may include lithium, beryllium, boron, sodium, magnesium, aluminum, potassium, calcium, scandium, titanium, vanadium, chromium, manganese, iron, cobalt, nickel, copper, zinc, gallium, germanium, rubidium, strontium, yttrium, zirconium, niobium, molybdenum, technetium, ruthenium, rhodium, palladium, silver, cadmium, indium, tin, antimony, tellurium, cesium, barium, lanthanum, lanthanide, hafnium, tantalum, tungsten, rhenium, osmium, iridium, platinum, gold, thallium, mercury, lead, bismuth, polonium, francium, radium, actinium or actinide. For example, the metal may zirconium or hafnium.

The ligand 32b coordinating to the metal 32a may be varied according to the metal 32a to adjust a boiling point of the precursor 32. In example embodiments, the ligand 32b may include a halogen such as fluoro, chloro, bromo or iodo, a hydroxyl group, ammine, an amine group having a carbon atom of about 1 to 10, amido or an amido group in which an alkyl group having a carbon atom of about 1 to about 10 is substituted for a hydrogen atom, an alkoxy group having a carbon atom of about 1 to about 10, an alkyl group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a β-ketoiminato group having a carbon atom of about 5 to about 20 or a β-diiminato group having a carbon atom of about 5 to about 20. These may be used alone or in a mixture thereof. For example, the ligand may include dimethylamido (N(CH₃)₂), ethyl methyl amido (NCH₃C₂H₅), diethylamido (N(C₂H₅)₂), ethyl dimethyl amine (N(CH₃)₂C₂H₅), diethyl methyl amine (N(C₂H₅)₂CH₃) or triethylamine (N(C₂H₅)₃).

In example embodiments, the precursor having the metal and the ligand may include tetrakis-ethylmethylamido-zirconium (Zr(NCH₃C₂H₅)₄), tetrakis-ethylmethylamido-hafnium (Hf(NCH₃C₂H₅)₄), tetrakis-diethylamido-zirconium (Zr(N(C₂H₅)₂)₄), tetrakis-diethylamido-hafnium (Hf(N(C₂H₅)₂)₄), tetrakis-dimethylamido-zirconium (Zr(N(CH₃)₂)₄), tetrakis-dimethylamido-hafnium (Hf(N(CH₃)₂)₄), tetrakis-ethyldimethylamine-zirconium (Zr(N(CH₃)₂C₂H₅)₄), tetrakis-ethyldimethylamine-hafnium (Hf(N(CH₃)₂C₂H₅)₄, tetrakis-diethylmethylamine-zirconium (Zr(N(C₂H₅)₂CH₃)₄), tetrakis-diethylmethylamine-hafnium (Hf(N(C₂H₅)₂CH₃)₄), tetrakis-triethylamine-zirconium (Zr(N(C₂H₅)₃)₄) or tetrakis-triethylamine-hafnium (Hf(N(C₂H₅)₃)₄). These may be used alone or in a mixture thereof.

In example embodiments, the electron donating compound may be water, hydrogen halide, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having about 3 to about 15, a diene compound having a carbon atom of about 4 to about 15, a β-diketone compound of having a carbon atom of about 5 to about 20, a β-ketoimine compound having a carbon atom of about 5 to about 20, a β-diimine compound having a carbon atom of about 5 to about 20, ammonia or a amine compound having a carbon compound of about 1 to about 10. Theses may be used alone or in a mixture thereof. Hydrogen halide may include hydrogen fluoride, hydrogen chloride, hydrogen bromide or hydrogen iodide. The diene compound may include cyclopentadiene or a cyclopentadiene in which an alkyl compound having a carbon atom of about 1 to about 10 is substituted for a hydrogen atom. The alcohol compound may include ethanol, methanol or butanol. The amine compound having a carbon atom of about 1 to about 10 may include a primary amine, a secondary amine or a tertiary amine. For example, the electron donating compound may include diethyl amine, dimethyl amine, ethyl methyl amine, ethyl dimethyl amine, diethyl methyl amine or triethyl amine.

In example embodiments, the precursor 32 may be introduced into the chamber 10 with a flow rate of about 50 sccm to about 1,000 sccm for about 0.1 seconds to about 10 seconds. The precursor 32 of a liquid state may be maintained outside of the chamber 10, e.g. a canister at a temperature of about 50° C. to about 90° C. The precursor 32 may be vaporized during introducing the precursor 32 into the chamber 10 to maintain the vapor state in the chamber 10.

In example embodiments, a reverse flow-preventing gas may be introduced into the chamber 10 through the fourth diverged gas line 14b of the second gas line 14 while the precursor 32 is introduced into the chamber 10. The reverse flow-preventing gas may prevent the precursor 32 from flowing back to the second gas line 14. The reverse flow-preventing gas may include an inactive gas.

In example embodiments, the electron donating compound 34 may be introduced into chamber 10 with a flow rate of about 15 seem to about 3,000 seem for about 0.1 second to about 10 seconds. The electron donating compound 34 of a liquid state may be maintained outside of the chamber 10, e.g. a canister at a temperature of about 20° C. to about 40° C. The electron donating compound 34 may be vaporized during introducing the electron donating compound 34 into the chamber 10 to maintain the vapor state into the chamber 10.

An introduction time of the precursor 32 and the electron donating compound 34 may be varied.

Referring to FIGS. 4 and 5A, after the precursor 32 is introduced into the chamber 10, the electron donating compound 34 may be introduced into the chamber 10. For example, the precursor 32 may be introduced into the chamber 10 through the first diverged gas line 12a of the first gas line 12 and then the electron donating compound 34 may be introduced into the chamber 10 through the first diverged gas line 12a of the first gas line 12.

Referring to FIGS. 4 and 5B, the precursor 32 and the electron donating compound 34 may be simultaneously introduced into the chamber 10 during a same time interval. For example, the electron donating compound 34 may be introduced into the chamber 10 through the second diverge gas line 12b of the first gas line 12 while the precursor 32 is introduced into the chamber 10 through the first diverged gas line 12a of the first gas line 12.

Referring to FIGS. 4 and 5C, after the precursor 32 and the electron donating compound 34 is simultaneously introduced into the chamber 10, the electron donating compound 34 may be additionally introduced into the chamber 10 without introducing the precursor 32. For example, after the precursor 32 and the electron donating compound 34 are simultaneously introduced into the chamber 10 through the first diverged gas line 12a and the second diverged gas line 12b of the first gas line 12, respectively, the electron donating compound 34 may be continuously introduced into the chamber 10 for a predetermined time without introducing the precursor 32.

Referring to FIGS. 4 and 5D, after the electron donating compound 34 is introduced into the chamber 10, the precursor 32 may be introduced into the chamber 10. For example, the electron donating compound 34 may be introduced into the chamber 10 through the second diverged gas line 12b of the first gas line 12 and then the precursor 32 may be introduced into the chamber 10 through the first diverged gas line 12b of the first gas line 12.

The electron donating compound 34 may be contacted with the precursor 32 to form the stabilized precursor 30. The metal 32a of the stabilized precursor 30 may be chemisorbed onto the substrate 20. Here, the electron donating compound 34 may be easily detached from the precursor 32 because the force between the metal 32a of the precursor 32 and the electron donating compound 34 is the weak intermolecular interaction.

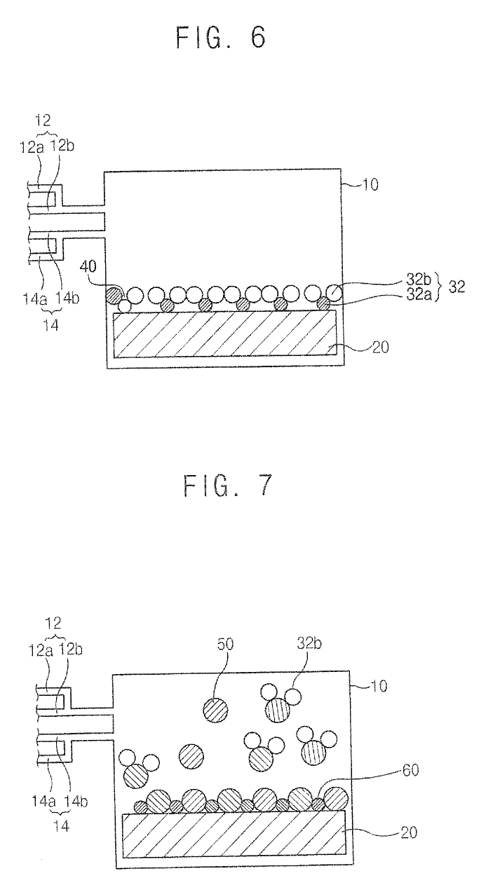

Referring to FIG. 6, the first purge gas may be provided onto the substrate 20 to form a preliminary first layer 40 including the precursor 32 on the substrate 20.

The first purge gas may remove the non-chemisorbed stabilized precursor 30, the non-chemisorbed precursor 32 and a remaining electron donating compound 34 from the substrate 20. The first purge gas may be introduced into the chamber 10 through the first gas line 12. The first purge gas may include an inactive gas such as an argon gas, a helium gas, a nitrogen gas or a neon gas, etc. The purge gas may be introduced into the chamber 10 with a flow rate of about 50 sccm to about 400 sccm for about 0.5 second to about 20 seconds.

In example embodiments, a reverse flow-preventing gas may be introduced into the chamber 10 through the fourth diverged gas line 14b of the second gas line 14 while the first purge gas is introduced into the chamber 10 through the second gas line 12. The reverse flow-preventing gas may prevent the non-chemisorbed stabilized precursor 30, the non-chemisorbed precursor 34 and the remaining electron donating compound 34 from flowing back through the second gas line 14.

Referring to FIG. 7, the reactant 50 is introduced into the chamber 10. The reactant 50 may be substituted for the ligand 32b of the precursor 32. The reactant 50 may react with the metal 32a of the precursor 32 to form a first layer 60 on the substrate 20.

In example embodiments, the reactant 50 may be introduced into the chamber 10 through the third diverged gas line 14a of the second gas line 14 with a flow rate of about 50 sccm to about 1,000 seem for about 2 seconds to about 5 seconds.

The reactant 50 may be varied according to reactivity with respect to the metal 32a of the precursor 32 and properties of the layer. In one example embodiment, the reactant 50 may include an oxidant. The oxidant may include ozone, an oxygen plasma, water or an ozone plasma. These may be used alone or in a mixture thereof. For example, when the oxidant is ozone which is easily treated, the layer including a metal oxide may have relative small amount of impurities. In other example embodiment, the reactant 50 may include a nitrogen atom. For example, the reactant 50 may include ammonia, nitrogen dioxide or nitrous oxide, etc.

In example embodiments, a reverse flow-preventing gas may be introduced into the chamber 10 through the second diverged gas line 12b of the first gas line 12 while the reactant 50 is introduced into the chamber 10 through the third diverged gas line 14a of the second gas line 14. The reverse flow-preventing gas may prevent the reactant 50 from flowing back through the first gas line 12.

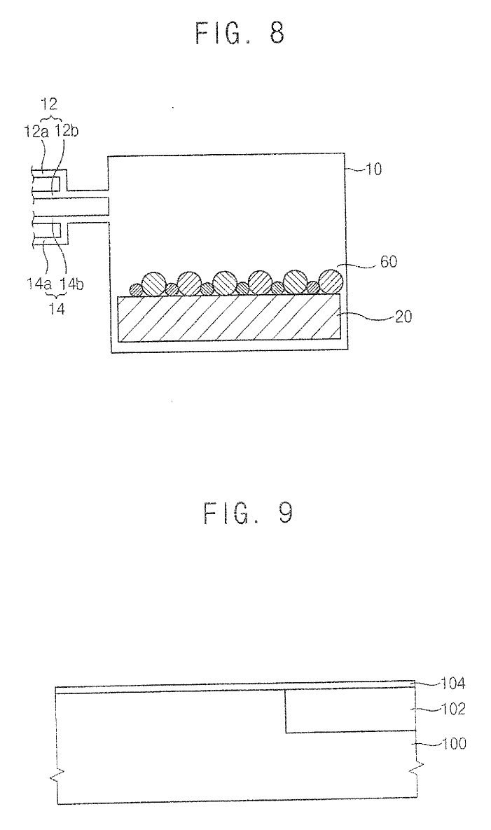

Referring to FIG. 8, a second purge gas may be introduced into the chamber 10 to remove the reactant 50 which do not chemically react with the metal 32a of the precursor 32 and the ligand 32b detached from the metal 32a. The second purge gas may be introduced into the chamber 10 through the fourth diverged gas line 14b of the second gas line 14. The second purge gas may include an inactive gas such as an argon gas, a helium gas, a nitrogen gas or a neon gas, etc. These may be used alone or in a mixture thereof. The second purge gas may be introduced into the chamber 10 with a flow rate of about 50 seem to about 400 seem for about 1 second to about 20 seconds.

In example embodiments, a reverse flow-preventing gas may be introduced into the chamber 10 through the second diverged gas line 12b of the first gas line 12 while the second purge gas is introduced into the chamber 10 through the fourth diverged gas line 14b of the second gas line 14. The reverse flow-preventing gas may prevent the reactant 50 which does not chemically react with the metal 32a of the precursor 32 and the ligand 32b detached from the metal 32a from flowing back through the first gas line 12.

The layer having a predetermined thickness may be formed by repeatedly performing an introduction of the precursor 32 and the electron donating compound 34, an introduction of the first purge gas, an introduction of the reactant 50 and an introduction of the second purge gas. The layer may include various materials according to the precursor 32 and the reactant 50. For example, when the reactant 50 is an oxidant, the layer may be a metal oxide. When the reactant 50 includes the nitrogen atom, the layer may include a metal nitride.

According to example embodiments, when the precursor 32 of the vapor state is contacted with the electron donating compound 34 of the vapor state, a thermal stability of the precursor 32 may be improved. Accordingly, a dissociation of the precursor 32 may be prevented before the precursor 32 is chemisorbed on the substrate 20. As a result, precipitates caused by a decomposition of the precursor 32 may be prevented from being reacted with the precursor 32 chemisorbed on the substrate 20. Further, the precipitates caused by a dissociation of the precursor 32 may be prevented from being chemisorbed on the upper portion of the hole, the trench, the gap or the recess and thus the precursor 32 may be uniformly diffused into the lower portion of the hole, the trench, the gap or the recess. Hence, the layer having good step coverage may be formed on the stepped portion of the substrate 20.

Hereinafter, a method of forming a gate structure will be explained in detail with reference to the accompanying drawings.

FIGS. 9 to 11 are cross-sectional views illustrating a method of forming a gate structure in accordance with example embodiments.

Referring to FIG. 9, an isolation layer 102 is formed on a substrate 100 including a cell region and a peripheral region to define an active region and a field region.

The isolation layer 102 may be formed on the substrate 100 by a shallow trench isolation (STI) process or a thermal oxidation process. The isolation layer 102 may include silicon oxide. The substrate 100 may include a semiconductor substrate such as silicon substrate, a germanium substrate, a silicon-germanium substrate, a silicon-on-insulator (SOI) substrate, a germanium-on-insulator (GOI) substrate, etc. Alternatively, the substrate may include a single crystalline metal oxide substrate. For example, the substrate may include a single crystalline aluminum oxide (Al₂O₃) substrate, a single crystalline strontium titanium oxide (SrTiO₃) substrate or a single crystalline magnesium oxide (MgO) substrate. The gate insulation layer 104 is formed on the substrate 100. The gate insulation layer 104 may have a thin equivalent oxidation thickness (EOT) and sufficiently reduce a leakage current. In example embodiments, the gate insulation layer 104 may be formed using a precursor stabilized by an electron donating compound.

When the precursor used for forming the gate insulation layer 104 is unstable to a heat, the precursor may be easily dissociated at a high temperature atmosphere required for a chemical vapor deposition (CVD) process or an atomic layer deposition (ALD) process. In example embodiments, when the precursor is contacted with the electron donating compound, the precursor may have improved thermal stability and thus the precursor may not easily disassociate at a high temperature atmosphere. The electron donating compound may donate an electron to a metal of the precursor to stabilize the precursor because an intermolecular interaction is formed between the precursor and the electron donating compound.

In formation of the gate insulation layer 104, the precursor stabilized by the electron donating compound may be provided onto the substrate 100. In one example embodiment, the precursor of a liquid state may be contacted with the electron donating compound to form the stabilized precursor. For example, the precursor of the liquid state may be mixed with the electron donating compound to form a precursor composition including the stabilized precursor. Here, the precursor composition may be vaporized to provide the stabilized precursor onto the substrate 100. In other example embodiment, the precursor of a vapor state may be contacted with the electron donating compound of a vapor state to form the stabilized precursor. For example, the precursor and the electron donating compound may be vaporized to be introduced onto the substrate 100, respectively. Thus, the precursor of the vapor state may be contacted with the electron donating compound of the vapor state on the substrate 100 to provide the stabilized precursor onto the substrate 100.

A reactant binding to the metal of the precursor is provided on the substrate 100 to form the gate insulation layer 104. The reactant may be substituted for a ligand of the precursor. The gate insulation layer 104 may be formed by a CVD process or an ALD process.

In one example embodiments, when the reactant includes an oxidant including an oxygen atom, the gate insulation layer 104 including a metal oxide may be formed on the substrate 100. For example, when the metal of the precursor includes zirconium and the reactant includes ozone, the gate oxide layer 104 including zirconium oxide may be formed on the substrate 100. Alternatively, when the precursor includes a first precursor including hafnium and a second precursor including zirconium and the reactant includes ozone, the gate oxide layer 104 including hafnium-zirconium oxide may be formed on the substrate 100.

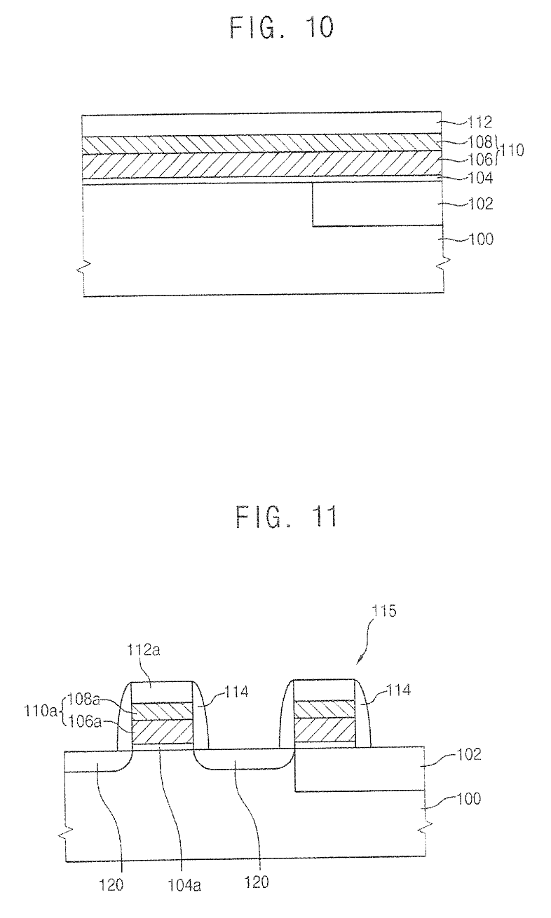

Referring to FIG. 10, a gate conductive layer 110 is formed on the gate insulation layer 104. The gate conductive layer 110 may include a polysilicon layer 106 on the gate insulation layer 104 and a metal silicide layer 108 on the polysilicon layer 106. Here, the metal silicide layer 108 may include tungsten silicide, tantalum silicide or cobalt silicide. A capping layer 112 may be formed on the gate conductive layer 110.

Referring to FIG. 11, the capping layer 112, the gate conductive layer 110 and the gate insulation layer 104 is patterned to form a gate structure 115 on the substrate 100. The gate structure 115 may include the gate insulation layer pattern 104a, a gate conductive layer pattern 110a including a polysilicon layer pattern 106a and a metal silicide layer pattern 108a and a capping layer pattern 112a. The gate structure 115 may be formed by a photolithography process.

A nitride layer is formed on the substrate 100 to cover the gate structure 115. An anisotropic etching process is performed at the nitride layer to form a gate spacer 114 on a sidewall of the gate structure 115. For example, the gate spacer 114 may be formed using silicon nitride.

Impurities are implanted into the substrate 100 adjacent to the gate structure 115 to form source/drain regions 120. For example, the source/drain regions 120 may be formed by an ion-implantation process using the gate structure 115 and the gate spacer 114 as an implantation mask.

According to example embodiments, the precursor is contacted with the electron donating compound to improve the thermal stability of the precursor. Therefore, the stabilized precursor may not be dissociated at a high temperature atmosphere to maintain the vapor state in the chamber in which the gate insulation layer is formed. As a result, precipitates caused by a dissociation of the precursor may not be generated and the precursor may be uniformly diffused onto the substrate to form a layer having a uniform thickness.

Hereinafter, a method of forming a capacitor will be explained in detail with reference to the accompanying drawings.

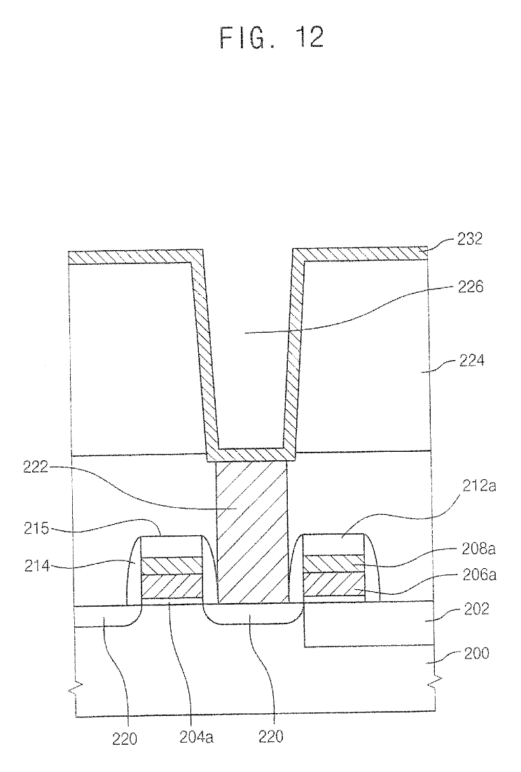

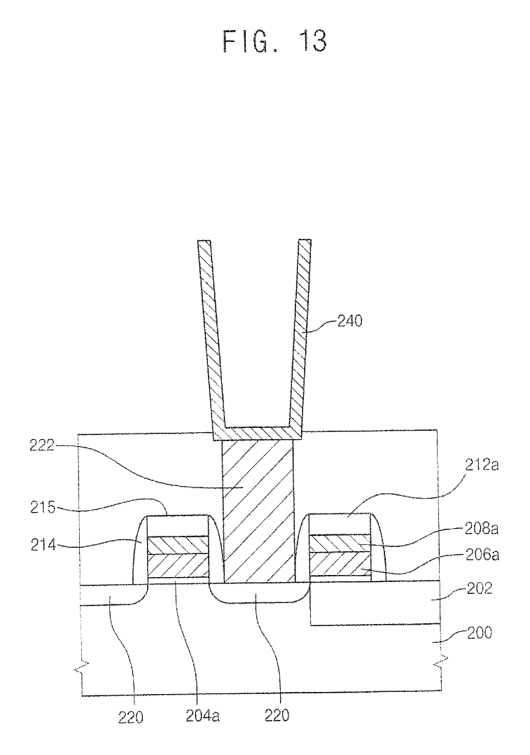

FIGS. 12 to 15 are cross-sectional views illustrating a method of manufacturing a capacitor in accordance with example embodiments.

Referring to FIG. 12, a substrate 200 is provided. A structure is formed on the substrate 200. The structure may include an isolation layer 202, a gate structure 215 including a gate insulation layer pattern 204a, a polysilicon layer pattern 206a, a metal silicide layer pattern 208a and a capping layer pattern 212a and a gate spacer 214 and a contact plug 222.

The insulating interlayer is formed on the substrate 200 to cover the contact plug 222. The insulating interlayer is partially removed until the contact plug 222 is exposed to form an insulating interlayer pattern 224 including a contact hole 226. The insulting interlayer pattern 224 may be formed using an oxide, a nitride or an oxynitride. For example, the insulating interlayer pattern 224 may include silicon oxide such as phosphor silicate glass (PSG), borophosphosilicate glass (BPSG), undoped silicate glass (USG), spin-on glass (SOG), flowable oxide (FOx), tetraethyl orthosilicate (TEOS), plasma-enhanced tetraethyl orthosilicate (PE-TEOS), high-density plasma chemical vapor deposition (HDP-CVD) oxide, etc.

A first conductive layer 232 is formed on the contact hole 226 and the insulating interlayer pattern 224. The first conductive layer 232 may be formed using titanium, titanium nitride, tantalum, tantalum nitride, polysilicon, tungsten, tungsten nitride or ruthenium.

Referring to FIG. 13, a lower electrode 240 is formed on contact plug 222. The lower electrode 240 may be electrically connected to the contact plug 222.

In formation of the lower electrode 240, a sacrificial layer (not illustrated) is formed on the first conductive layer 232. The sacrificial layer and the first conductive layer 232 are partially removed until the insulation interlayer pattern 224 is exposed. The sacrificial layer may be formed using an oxide such as silicon oxide. The sacrificial layer remaining in the contact hole 226 and the insulating interlayer pattern 224 is removed to form the lower electrode 240.

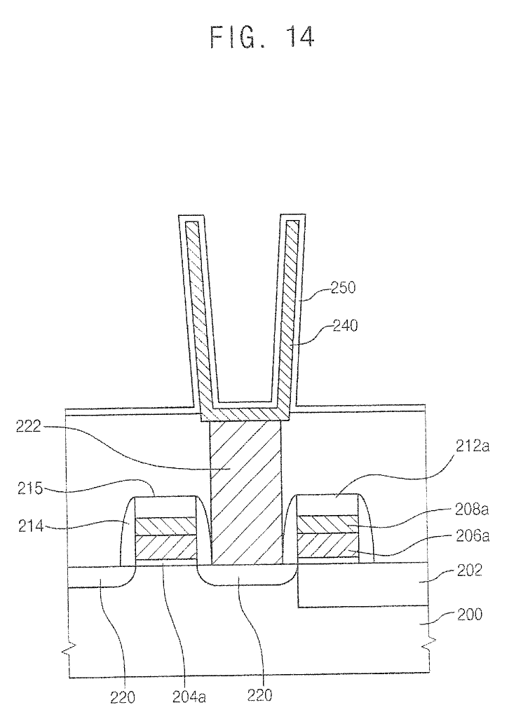

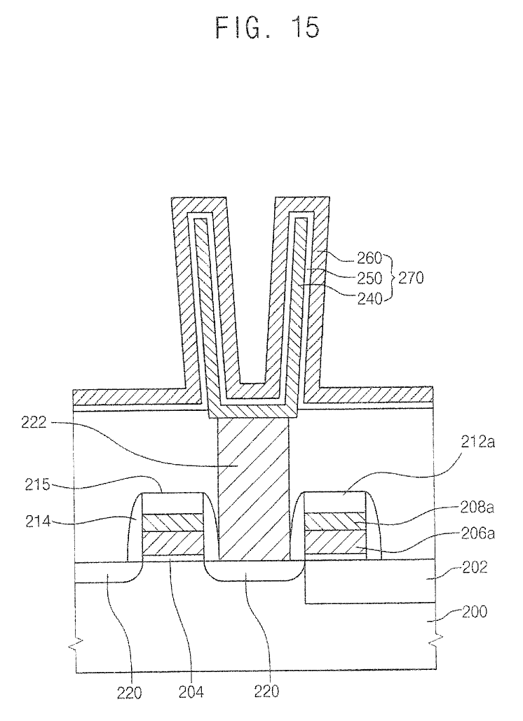

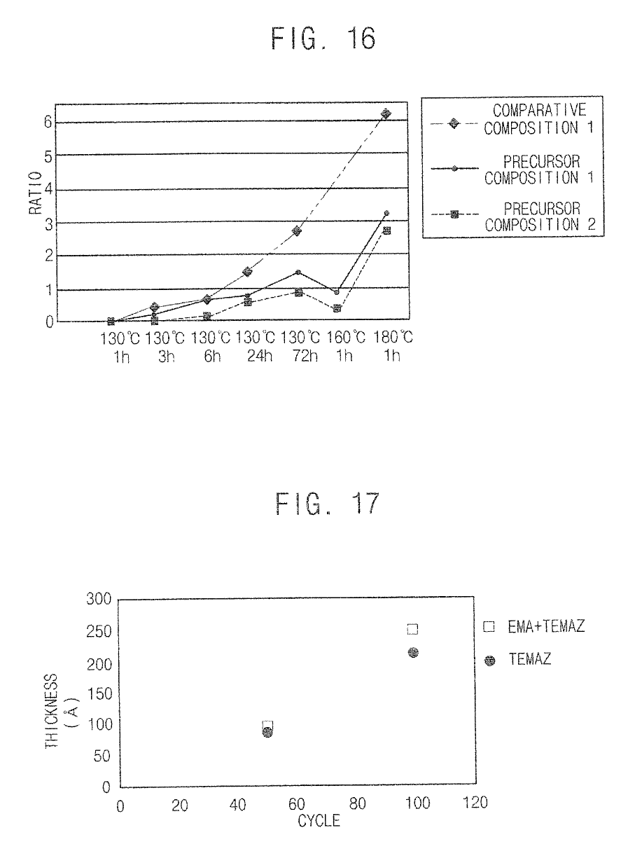

Referring to FIG. 14, a dielectric layer 250 is formed on the lower electrode 240. The dielectric layer 250 may have a thin equivalent oxidation thickness (EOT), a high dielectric constant and a uniform thickness from a surface of the lower electrode 240. In example embodiments, the dielectric layer 250 may be formed using a precursor contacted with an electron donating compound. The precursor contacted with an electron donating compound may have improved thermal stability. When the precursor is contacted with the electron donating compound, the electron donating compound may donate an electron to a metal of the precursor to stabilize the precursor because an intermolecular interaction is formed between the precursor and the electron donating compound. When the precursor used for forming the dielectric layer 250 is unstable to heat, the ligand of the precursor may be easily detached from the metal of the precursor and thus the thickness of the dielectric layer 250 may not be efficiently controlled. Additionally, precipitates caused by dissociation of the precursor may be deposited on an upper portion of the lower electrode 240 to prevent the precursor from being uniformly diffused into a lower portion of the lower electrode 240. According to example embodiments, when the thermal stability of the precursor is improved, the thickness of the dielectric layer 250 may be efficiently adjusted and the precursor may be uniformly diffused into the lower portion of the lower electrode 240 without a dissociation of the precursor. Accordingly, the dielectric layer 250 formed using the stabilized precursor may have a good step coverage.

In formation of the dielectric layer 250, the precursor stabilized by the electron donating compound is provided on the lower electrode 240.

In one example embodiment, the precursor of the liquid state may be contacted with the electron donating compound of the liquid state. For example, the precursor of the liquid state may be mixed with the electron donating compound of the liquid state to form a precursor composition. Here, the precursor composition may be vaporized to provide the stabilized precursor on the substrate 200 on which the lower electrode 240 is formed. In other example embodiment, the precursor of the vapor state may be contacted with the electron donating compound of the vapor state. For example, the precursor and the electron donating compound may be vaporized to be provided on the lower electrode 240, respectively. The vaporized precursor may be contacted with the electron donating compound to provide the stabilized precursor on the substrate 200 on which the lower electrode 240 is formed.

The stabilized precursor is reacted with a reactant to form the dielectric layer 250 on the lower electrode 240. The reactant may be substituted for the ligand of the precursor. The dielectric layer 250 may be formed by a CVD process or an ALD process.

In example embodiments, when the reactant is an oxidant including an oxygen atom, the dielectric layer 250 may include a metal oxide. For example, when the metal of the precursor is zirconium and the reactant includes ozone, the dielectric layer 250 including zirconium oxide may be uniformly formed on the lower electrode 240. For example, when the precursor includes a first precursor including zirconium and a second precursor including hafnium and the reactant includes ozone, the dielectric layer 250 including hafnium-zirconium oxide may be uniformly formed on the lower electrode 240.

Referring to FIG. 15, an upper electrode 260 is formed on the dielectric layer 250 to form a capacitor 270 including the lower electrode 240, the dielectric layer 250 and the upper electrode 260. The upper electrode 260 may be formed using titanium, titanium nitride, tantalum, tantalum nitride, polysilicon, tungsten, tungsten nitride or ruthenium.

According to example embodiments, the capacitor 270 may be formed using the precursor stabilized by the electron donating compound. The stabilized precursor may have an improved thermal stability. As a result, the precursor may not be dissociated at a high temperature atmosphere so that the precursor may be uniformly diffused into the lower portion of the lower electrode to form the dielectric layer having good step coverage. Thus, the leakage currents may be efficiently reduced between the upper electrode 260 and the lower electrode 240.

Hereinafter, characteristics of the precursor and the layer formed using the precursor will be evaluated.

Evaluation of a Thermal Stability of a Precursor

Experiment 1

A precursor of a liquid state is contacted with an electron donating compound to evaluate a thermal stability of the precursor. Results are illustrated in Table 1, Table 2 and FIG. 16.

In evaluation of the thermal stability of the stabilized precursor, tetrakis-ethylmethyl amido-zirconium (TEMAZ, Zr(NHCH₃C₂H₅)₄) was used as the precursor and ethyl methyl amine (EMA, NHCH₃C₂H₅) was used as the electron donating compound.

Tetrakis-ethylmethyl amido-zirconium of the liquid state was mixed with ethyl methyl amine at a room temperature to form a precursor composition. The precursor composition was heated to about 130° C. to measure a Gardner index of the precursor composition using a calorimeter OME 2000, manufactured by Nippon Denshoku Instrument in Japan. As the Gardner index is higher, a color of the precursor composition is deeper so that generation of precipitates is larger in the precursor composition.

A precursor composition 1 and a precursor composition 2 were prepared. The precursor composition 1 and the precursor composition 2 were prepared by mixing tetrakis-ethylmethyl amido-zirconium and ethyl methyl amine with a mole ratio of about 1:1 and about 1:2, respectively. A comparative composition 1 including only tetrakis-ethylmethyl amido-zirconium was prepared. The precursor composition 1, the precursor composition 2 and the comparative composition 1 were heated to about 130° C. Then, the Gardner index of the precursor compositions 1 and 2 and the comparative composition 1 were measured with the calorimeter OME 2000 while the precursor compositions 1 and 2 and the comparative composition 1 were maintained at a temperature of about 130° C. for about 24 hours. Results are illustrated in Table 1.

TABLE 1

| | Precursor | Precursor | Comparative |
|---|---|---|---|
| Temperature/time | composition 1 | composition 2 | composition 1 |
| Room temperature | 0.2 | 0.2 | 0.2 |
| 130° C./6 hours | 2.0 | 2.0 | 5.3 |
| 130° C./12 hours | 5.3 | 5.0 | 7.0 |
| 130° C./24 hours | 7.2 | 6.8 | 19.0 |

Referring to Table 1, the precursor compositions 1 and 2 and the comparative composition 1 were a substantially transparent liquid state at a room temperature. After about 6 hours at a temperature of about 130° C., the Gardner index of the precursor compositions 1 and 2 was not rapidly increased. However, the Gardner index of the comparative composition 1 was rapidly increased. Thus, it was confirmed that precipitates caused by dissociation of tetrakis-ethylmethyl amido-zirconium were generated in the comparative composition 1 after about 6 hours at a temperature of about 130° C. Further, after about 12 hours at a temperature of about 130° C. the Gardner index of the precursor compositions 1 and 2 was substantially less than the Gardner index of the comparative composition 1. Accordingly, it is confirmed that tetrakis-ethylmethyl amido-zirconium of the liquid state contacted with ethyl methyl amine may not be dissociated for a long time at a high temperature atmosphere.

Table 2 illustrates a thermal stability of the stabilized precursor in the precursor composition according to a mole ratio of the precursor and the electron donating compound.

Precursor compositions 3 to 11 were prepared by mixing tetrakis-ethylmethyl amido-zirconium and ethyl methyl amine with a mole ratio of about 1:0.02, about 1:0.05, about 1:0.1, about 1:0.2, about 1:0.3, about 1:0.5, about 1:0.7, about 1:3 and about 1:4, respectively. After the precursor compositions 1 to 11 and the comparative composition 1 were heated to about 160° C. and were kept for about 1 hour, a Gardner index of the precursor compositions 1 to 11 and the comparative composition 1 was measured using the calorimeter OME 2000, manufactured by Nippon Denshoku Instrument in Japan. Results are illustrated in Table 2.

TABLE 2

| | Gardner index |
|---|---|
| Comparative composition 1 | 18.2 |
| Precursor composition 1 | 6.6 |
| Precursor composition 2 | 5.3 |
| Precursor composition 3 | 12.1 |
| Precursor composition 4 | 11.3 |
| Precursor composition 5 | 10.6 |
| Precursor composition 6 | 10.2 |
| Precursor composition 7 | 10.0 |
| Precursor composition 8 | 9.8 |
| Precursor composition 9 | 8.2 |
| Precursor composition 10 | 4.0 |
| Precursor composition 11 | 3.6 |

Referring to Table 2, the comparative composition 1 had a highest Gardner index and thus it was confirmed that plenty of tetrakis-ethylmethyl amido-zirconium was dissociated. The precursor compositions 1 to 11 had a substantially lower Gardner index than the comparative composition 1. Accordingly, it was confirmed that tetrakis-ethylmethyl amido-zirconium was less dissociated in the precursor compositions 1 to 11 than in the comparative composition 1. Further, the precursor compositions 1, 2, 10 and 11 had a much lower Gardner index than that of the comparative composition 1. Thus, it is confirmed that when the mole ratio of the electron donating compound with respect to the precursor is more than about 1, a dissociation of the precursor is efficiently prevented.

FIG. 16 represents a graph illustrating a ratio of solid residues weight with respect to a weight of the precursor compositions 1 and 2 and the comparative composition 1. The solid residues were generated by a dissociation of the precursor. The precursor compositions 1 and 2 and the comparative composition 1 were heated to a predetermined temperature and then were kept for predetermined time. Then a thermalgravimetric analysis (TGA) was performed to measure a ratio of solid residues weight with respect to a weight of the precursor compositions 1 and 2 and the comparative composition 1.

The precursor compositions 1 and 2 and the comparative composition 1 were heated to about 130° C. and were kept for about 1 hour, about 3 hours, about 6 hours, about 24 hours or 72 hours. Further, The precursor compositions 1 and 2 and the comparative composition 1 were heated to about 160° C. or 180° C. and were kept for about 1 hour. Then, TGA was performed. In performing TGA, the precursor compositions 1 and 2 and the comparative composition 1 were heated from 30° C. to about 200° C. with a ratio of about 10° C./min. The results are illustrated in FIG. 16. A ratio in FIG. 16 represents percent (%).

Referring to FIG. 16, plenty of the solid residues was generated in the comparative composition 1 which was kept for about 24 hours at a temperature of about 130° C. Further, the solid residues weight in the comparative composition 1 was two times more than those in the precursor compositions 1 and 2 at a temperature of about 160° C. and about 180° C.

The solid residues weight with respect to the weight was not rapidly increased in the precursor compositions 1 and 2 which were kept for about 6 hours at a temperature of about 130° C. Additionally, the solid residues weight with respect to the weight of the precursor compositions 1 and 2 was less than that of the comparative composition 1 at a temperature of about 160° C. and about 180° C. Additionally, the solid residues weight with respect to the weight of the precursor composition 2 was relatively less than the solid residues weight with respect to the weight of the precursor composition 1.

It is confirmed from Table 1, Table 2 and FIG. 16 when the precursor composition including tetrakis-ethylmethyl amido-zirconium and ethyl methyl amine is vaporized, the dissociation of tetrakis-ethylmethyl amido-zirconium is reduced for a long time at a high temperature atmosphere.

Experiment 2

A precursor of a vapor state is contacted with an electron donating compound to evaluate a thermal stability of the precursor.

In evaluation of the thermal stability of the stabilized precursor, tetrakis-ethylmethyl amido-zirconium (TEMAZ, Zr(NHCH₃C₂H₅)₄) was used as the precursor and ethyl methyl amine (EMA, NHCH₃C₂H₅) was used as the electron donating compound.

It was observed with naked eyes that a color of a gas line which only vaporized tetrakis-ethylmethyl amido-zirconium passed through and a color of a gas line which tetrakis-ethylmethyl amido-zirconium and ethyl methyl amine simultaneously passed through. Indication of the color on an inner wall of the gas line represents the generation of precipitates caused by dissociation of tetrakis-ethylmethyl amido-zirconium.

Tetrakis-ethylmethyl amido-zirconium was vaporized in a bubbling system by bubbling tetrakis-ethylmethyl amido-zirconium with a carrier gas. Vaporized tetrakis-ethylmethyl amido-zirconium passed through the gas lines having a length of about 1 m and having a temperature of about 100° C., about 150° C., about 200° C. and about 250° C., respectively, with the carrier gas. Each of the gas lines was observed with naked eyes to confirm the generation of the precipitates through the change of the color. At the same atmosphere, tetrakis-ethylmethyl amido-zirconium and ethyl methyl amine were vaporized in the bubbling system by bubbling tetrakis-ethylmethyl amido-zirconium and ethyl methyl amine, respectively, with the carrier gas to introduce vaporized tetrakis-ethylmethyl amido-zirconium and vaporized ethyl methyl amine into the gas lines, respectively. Vaporized tetrakis-ethylmethyl amido-zirconium and the vaporized ethyl methyl amine passed through the gas lines with a mole ratio of about 1:1 and 1:17, respectively, to confirm the generation of the precipitates.

Precipitates were deposited on the gas lines, which only vaporized tetrakis-ethylmethyl amido-zirconium passed through, from about 150° C. Precipitates were deposited on the gas lines which vaporized tetrakis-ethylmethyl amido-zirconium and vaporized ethyl methyl amine passed through, from about 250° C. Accordingly, it was confirmed that ethyl methyl amine may improve a thermal stability of tetrakis-ethylmethyl amido-zirconium of the vapor state.

Evaluation of a Deposition Rate of a Precursor

Experiment 3

A deposition rate of a precursor stabilized by an electron donating compound was evaluated by performing an ALD process. Tetrakis-ethylmethyl amido-zirconium (TEMAZ, Zr(NHCH₃C₂H₅)₄) was used as the precursor and ethyl methyl amine (EMA, NHCH₃C₂H₅) was used as the electron donating compound.

A canister including tetrakis-ethylmethyl amido-zirconium was set at a temperature of about 80° C. and a canister including ethyl methyl amine was set at a temperature of about 20° C. A chamber was set at a temperature of about 340° C. After tetrakis-ethylmethyl amido-zirconium and ethyl methyl amine were vaporized in a bubbling system, tetrakis-ethylmethyl amido-zirconium of the vapor state and ethyl methyl amine of the vapor state were simultaneously introduced with an argon gas as a carrier gas into the chamber during same time interval. A flow rate of the argon gas was about 1,000 sccm. Then, ozone was introduced as a reactant which was substituted for a ligand of the precursor to form a zirconium oxide layer on a substrate. A thickness of the zirconium oxide layer was measured. Results are illustrated in FIG. 17. At the same atmosphere, an ALD process was performed using only tetrakis-ethylmethyl amido-zirconium to measure a thickness of a zirconium oxide layer per a cycle of the ALD process. Results are illustrated in FIG. 17.

Referring to FIG. 17, when the zirconium oxide layer was formed using tetrakis-ethylmethyl amido-zirconium stabilized by ethyl methyl amine, the thickness of the zirconium oxide layer is substantially thicker compared to the case using only tetrakis-ethylmethyl amido-zirconium. Thus, when the ALD process is performed using both tetrakis-ethylmethyl amido-zirconium and ethyl methyl amine, the deposition rate was increased.

Evaluation of Step Coverage

Experiment 4

A step coverage of a layer is evaluated when the layer is formed using a precursor stabilized by an electron donating compound. Tetrakis-ethylmethyl amido-zirconium (TEMAZ, Zr(NHCH₃C₂H₅)₄) was used as the precursor and ethyl methyl amine (EMA, NHCH₃C₂H₅) was used as the electron donating compound.

A canister including tetrakis-ethylmethyl amido-zirconium was set at a temperature of about 80° C. and a canister including ethyl methyl amine was set at a temperature of about 20° C. A chamber was set at a temperature of about 340° C. After tetrakis-ethylmethyl amido-zirconium and ethyl methyl amine were vaporized in a bubbling system, tetrakis-ethylmethyl amido-zirconium of the vapor state and ethyl methyl amine of the vapor state were simultaneously introduced with an argon gas as a carrier gas into the chamber during a same time interval. A flow rate of the argon gas was about 1,000 sccm. Then, ozone was introduced as a reactant which was substituted for a ligand of the precursor to form a zirconium oxide layer on a cylindrical lower electrode having an aspect ratio of about 20:1. At the same atmosphere, a zirconium oxide layer was formed on a cylindrical lower electrode having an aspect ratio of about 20:1 using only tetrakis-ethylmethyl amido-zirconium. Each of the zirconium oxide layers was inspected using a scanning electron microscope (SEM). The results are illustrated in FIGS. 18A and 18B.

Referring to FIGS. 18A and 18B, a dielectric layer was uniformly formed on a bottom of a lower electrode in FIG. 18A. However, a dielectric layer was not uniformly formed on a bottom of a lower electrode in FIG. 18B. Further, a thickness of the dielectric layer on a top of the lower electrode was about 14.79 nm and a thickness of the dielectric layer on the bottom of the lower electrode was about 12.45 nm in FIG. 18A and it was confirmed that the dielectric layer had a uniform thickness. A thickness of the dielectric layer on a top of the lower electrode was about 14.01 nm and a thickness of the dielectric layer on the bottom of the lower electrode was about 10.32 nm in FIG. 18B and it was confirmed that the thickness of the dielectric layer was not uniform. Thus, it was confirmed when tetrakis-ethylmethyl amido-zirconium was stabilized by ethyl methyl amine, step coverage of the zirconium oxide layer was improved and the zirconium oxide layer having a uniform thickness was formed.

According to example embodiments, the precursor stabilized by the electron donating compound may have an improved thermal stability. That is, the precursor stabilized by the electron donating compound may not be dissociated at a high temperature atmosphere. Accordingly, when the layer is formed using the precursor stabilized by the electron donating compound, the precursor may be uniformly diffused into the lower portion of the hole, the trench, the gap or the recess without dissociation of the precursor. As a result, the layer having good step coverage may be efficiently formed on an object and thus a semiconductor device having an improved stability and reliability may be manufactured.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of forming a layer comprising:
stabilizing a precursor by contacting the precursor with an electron donating compound to provide a stabilized precursor into a substrate, the precursor including a metal and a ligand coordinating to the metal; and
introducing a reactant into the substrate to bind to the metal in the stabilized precursor.

2. The method of claim 1, wherein the electron donating compound includes at least one selected from the group consisting of water, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound having a carbon atom of about 5 to about 20, a β-ketoimine compound having a carbon atom of about 5 to about 20, a β-diimine compound having a carbon atom of about 5 to about 20, ammonia and a amine compound having a carbon compound of about 1 to about 10.

3. The method of claim 1, wherein the metal in the precursor includes a metal selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), cesium (Cs), barium (Ba), lanthanum (La), lanthanide (Ln), hafnium (Hf), tantalum (Ta), tungsten (W), rhenium (Re), osmium (Os), iridium (Ir), platinum (Pt), gold (Ag), thallium (Tl), mercury (Hg), lead (Pb), bismuth (Bi), polonium (Po), francium (Fr), radium (Ra), actinium (Ac) and actinide (An).

4. The method of claim 1, wherein the metal in the precursor includes zirconium or hafnium and the electron donating compound includes a primary amine, a secondary amine or a tertiary amine, the primary amine, the secondary amine and the tertiary amine having a carbon atom of about 1 to about 10.

5. The method of claim 4, wherein the secondary amine includes at least one selected from the group consisting of dimethyl amine, diethyl amine and ethyl methyl amine and the tertiary amine includes at least one selected from the group consisting of ethyl dimethyl amine, diethyl methyl amine and triethyl amine.

6. The method of claim 1, wherein the electron donating compound is contacted with the precursor including zirconium or hafnium to form the stabilized precursor represented by formula 1: 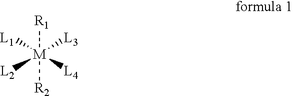
wherein the formula 1, M represents zirconium or hafnium, L₁ to L₄ independently represent fluoro (F), chloro (Cl), bromo (Br), iodo (I), an alkoxy group having a carbon atom of about 1 to about 10, an aryl group having a carbon atom of about 6 to about 12, an allyl group having a carbon atom of about 3 to about 15, a dienyl group having a carbon atom of about 4 to about 15, a β-diketonate group having a carbon atom of about 5 to about 20, a β-ketoiminato group having a carbon atom of about 5 to about 20, a β-diiminato group having a carbon atom of about 5 to about 20, a hydroxyl group (OH), ammine (NH₃), an amine group having a carbon atom of about 1 to 10, amido (NH₂) or an amido group in which an alkyl group having a carbon atom of about 1 to about 10 is substituted for a hydrogen atom and R₁ and R₂ independently represent hydrogen fluoride (HF), hydrogen chloride (HCl), hydrogen bromide (HBr), hydrogen iodide (HI), water, an alcohol compound having a carbon atom of about 1 to about 10, an ether compound having a carbon atom of about 2 to about 10, a ketone compound having a carbon atom of about 3 to about 10, an aryl compound having a carbon atom of about 6 to about 12, an allyl compound having a carbon atom of about 3 to about 15, a diene compound having a carbon atom of about 4 to about 15, a β-diketone compound of having a carbon atom of about 5 to about 20, a β-ketoimine compound having a carbon atom of about 5 to about 20, a β-diimine compound having a carbon atom of about 5 to about 20, ammonia or an amine compound having a carbon atom of about 1 to about 10.

7. The method of claim 1, wherein the precursor includes at least one precursor selected from the group consisting of tetrakis-ethylmethylamido-zirconium (Zr(NCH₃C₂H₅)₄), tetrakis-ethylmethylamido-hafnium (Hf(NCH₃C₂H₅)₄), tetrakis-diethylamido-zirconium (Zr(N(C₂H₅)₂)₄), tetrakis-diethylamido-hafnium (Hf(N(C₂H₅)₂)₄), tetrakis-dimethylamido-zirconium (Zr(N(CH₃)₂)₄), tetrakis-dimethylamido-hafnium (Hf(N(CH₃)₂)₄), tetrakis-ethyldimethylamine-zirconium (Zr(N(CH₃)₂C₂H₅)₄), tetrakis-ethyldimethylamine-hafnium (Hf(N(CH₃)₂C₂H₅)₄), tetrakis-diethylmethylamine-zirconium (Zr(N(C₂H₅)₂CH₃)₄), tetrakis-diethylmethylamine-hafnium (Hf(N(C₂H₅)₂CH₃)₄), triethylamine-zirconium (Zr(N(C₂H₅)₃)₄) and tetrakis-triethylamine-hafnium (Hf(N(C₂H₅)₃)₄).

8. The method of claim 1, wherein providing the stabilized precursor into the substrate comprises:
mixing the precursor and the electron donating compound to prepare a precursor composition; and
vaporizing the precursor composition to provide the stabilized precursor into the substrate.

9. The method of claim 8, wherein the precursor composition includes the precursor and the electron donating compound with a mole ratio of about 1:0.01 to about 1:12.

10. The method of claim 1, wherein providing the stabilized precursor into the substrate comprises:
introducing the precursor and the electron donating compound into the substrate, respectively; and
contacting the precursor with the electron donating compound on the substrate to provide the stabilized precursor into the substrate.

11. The method of claim 10, wherein the precursor and the electron donating compound are simultaneously introduced into the substrate during a same time interval.

12. The method of claim 10, wherein the electron donating compound is further introduced into the substrate after the precursor and the electron donating compound are introduced into the substrate during a same time interval.

13. The method of claim 10, wherein the electron donating compound is introduced after the precursor is introduced into the substrate.

14. The method of claim 10, wherein the precursor is introduced after the electron donating compound is introduced into the substrate.

15. A method of forming a gate structure comprising:
stabilizing a precursor by contacting the precursor with an electron donating compound to provide a stabilized precursor into a substrate, the precursor including a metal and a ligand coordinating to the metal;
introducing a reactant binding to the metal in the stabilized precursor into the substrate to form a gate insulation layer;
forming a gate conductive layer on the gate insulation layer; and
etching the gate insulation layer and the gate conductive layer.

16. A method of forming a capacitor comprising:
forming a lower electrode on a substrate;
stabilizing a precursor by contacting the precursor with an electron donating compound to provide a stabilized precursor into a substrate, the precursor including a metal and a ligand coordinating to the metal;
introducing a reactant binding to the metal of the precursor into the substrate to form a dielectric layer; and
forming an upper electrode on the dielectric layer.

17-20. (canceled)
